(19) United States
(12) Patent Application Publication
(10) Pub. No.: US 2016/0306023 A1
(43) Pub. Date: Oct. 20, 2016

(54) SYSTEM FOR MEASURING CORTICAL THICKNESS FROM MR SCAN INFORMATION

(71) Applicant: KONINKLIJKE PHILIPS N.V., Eindhoven (NL)

(72) Inventors: LYUBOMIR GEORGIEV ZAGORCHEV, EINDHOVEN (NL); CARSTEN MEYER, EINDHOVEN (NL); ASTRID RUTH FRANZ, EINDHOVEN (NL); THOMAS HEIKO STEHLE, EINDHOVEN (NL); JUERGEN WEESE, EINDHOVEN (NL); FABIAN WENZEL, EINDHOVEN (NL); MARCEL BREEUWER, EINDHOVEN (NL); VELJKO POPOV, EINDHOVEN (NL); SEBASTIAN FLACKE, EINDHOVEN (NL)

(21) Appl. No.: 15/038,059

(22) PCT Filed: Nov. 12, 2014
(86) PCT No.: PCT/IB2014/065972

§ 371 Date: May 20, 2016

Related U.S. Application Data
(60) Provisional application No. 61/907,773, filed on Nov. 22, 2013.

(51) Int. Cl. G01R 33/56; G01R 33/48

(52) U.S. Cl. CPC G01R 33/5608; G01R 33/4828

(57) ABSTRACT

A measurement apparatus (800) to measure cortical thickness, the measurement apparatus may include at least one controller (810) which may be configured to: obtain magnetic resonance (MR) scan information of a region-of-interest of at least a portion of a cerebral cortex of a subject; form first, second and third meshes each comprising a plurality of points situated apart from each other, the first and third meshes being situated at inner and outer cortical boundary layers, respectively, of the cerebral cortex and the second mesh being situated between the first and third meshes; and/or for each of a plurality of points of the second mesh: determine a closest point of the first mesh and a closest point of the third mesh, determine a distance between the corresponding closest point of the first mesh and the corresponding closest point of the third mesh, said distance being corresponding with a cortical thickness.

The present system relates to system for measuring cortical thickness and, more particularly, to system for quantification of cortical thickness in magnetic resonance (MR) volumes, and a method of operation thereof.

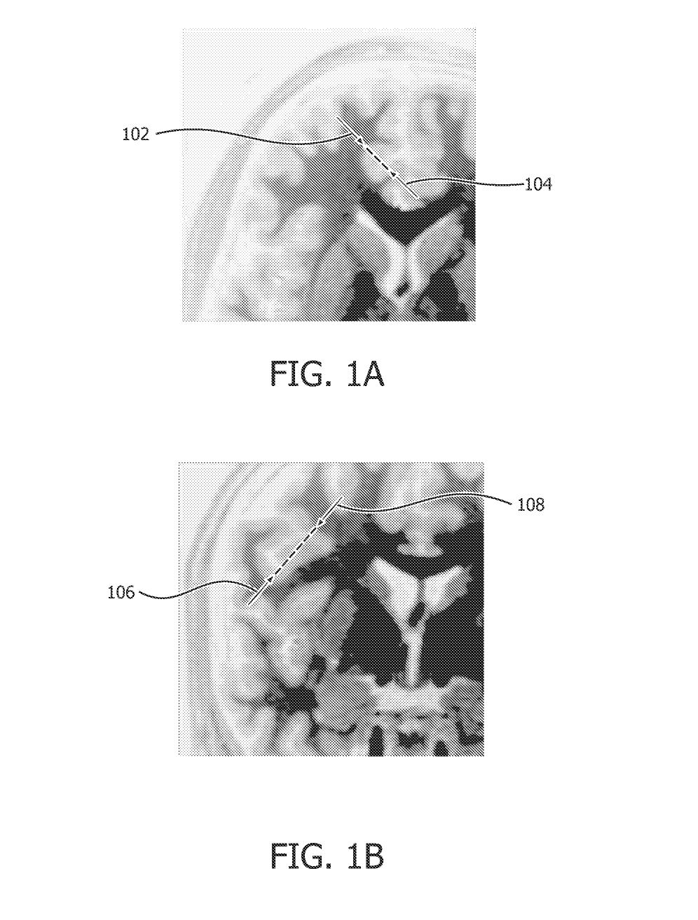

The cerebral cortex is the outmost layer of tissue that covers the white matter tracts in the brain. FIG. 1A shows a T1w scan of an axial cross-section of a cerebral cortex depicted as the outermost dark area. The cerebral cortex has a dark grey appearance on standard T1w MR scans, as illustrated in FIG. 1B which shows a T1w scan of a coronal cross-section of a cerebral cortex. In healthy human subjects, the cortical mantle is a relatively thin layer of tissue which ranges in thickness from about 2 to about 4 mm and is the main information processing center of the brain. Existing work has shown that the cerebral cortex (hereinafter “cortex” for the sake of simplicity) plays a very important role in a large number of neurodegenerative disorders such as Alzheimer's disease, Schizophrenia, etc. Moreover, the thinning of the cortical mantle has been correlated with disease progression and, thus, may be used as a diagnostic imaging biomarker in accordance with embodiments of the present system.

Since its introduction, structural MR has posed the widespread acceptance of the need for objective, accurate, and reproducible quantification of results rather than subjective opinion. With reference to FIGS. 1A and 1B, cortical arrows 102 and 104; 106 and 108 illustrate a thickness of the cortical mantle in corresponding locations. Once MR data is acquired, quantification is essential for reliable evaluation of this acquired data. The added value of volumetric (3-D) information allows for comparisons to be made more easily, for more reliable detection of biological variation between subjects, and for more accurate diagnosis of disease.

The parcellation of the cortex from MR volumes, however, is a complex and labor intensive procedure. Currently, most clinical centers use MR data for qualitative visual inspection of cortical thinning and/or side-by-side comparisons which are manually performed by a professional. Conventional software tools simply measure the thickness of the cortex on single two-dimensional (2-D) planes and fall short of providing a correct quantitative representation. Only a few existing software tools may capture a true volumetric description of the cortical mantle but their technical methodology and derived measurements vary from one clinical center to another. Some of the technical difficulties include: limited grey/white matter contrast, inability to segment the cortical boundary accurately, and most importantly, the absence of a standardized technique for quantifying the segmented thickness. The lack of an established standard adversely affects the reproducibility and outcome of clinical studies.

The system(s), device(s), method(s), user interface(s), computer program(s), processes, etc. (hereinafter each of which will be referred to as system, unless the context indicates otherwise), described herein address problems in prior art systems.

In accordance with embodiments of the present system, there is disclosed a measurement apparatus which may include at least one controller which is configured to: obtain magnetic resonance (MR) scan information of a region-of-interest (ROI) of at least a portion of a cerebral cortex of a subject; form first, second and third meshes each comprising a plurality of points situated apart from each other, the first and third meshes being situated at inner and outer cortical boundary layers, respectively, of the cerebral cortex and the second mesh being situated between the first and third meshes; and/or for each of a plurality of points of the second mesh: determine a closest point of the first mesh and a closest point of the third mesh, determine a distance between the corresponding closest point of the first mesh and the corresponding closest point of the third mesh, and/or associate the determined distance with the corresponding point of the plurality of points of the second mesh. The inner (e.g., the first) and outer (third) meshes may be topologically identical; they may have the same number of vertices and triangles and there may be a one-to-one mapping between these two meshes. The medial (second) mesh may be computed in accordance with the one-to-one mapping.

It is also envisioned that the at least one controller may be further configured to map the associated distance for each of the plurality of points of the second mesh in accordance with a mapping method to form content. Moreover, the at least one controller may be further configured to render the content on a display. In accordance with embodiments of the present system, the mapping method may be selected by a user from a plurality of mapping methods rendered on a display. Moreover, the at least one controller may be further configured to associate the points of the first and third meshes, which are determined to be closest to the same point on the second mesh, with each other. It is also envisioned that the at least one controller may be further configured to determine a cortical thickness at one or more selected points of the plurality of points of the second mesh based upon the determined distance associated with the selected point.

In accordance with other embodiments of the present system, there is disclosed a method of measuring, the method performed by at least one controller of an imaging system, the method may include acts of: obtaining magnetic resonance (MR) scan information of a region-of-interest (ROI) of at least a portion of a cerebral cortex of a subject; forming first, second and third meshes each comprising a plurality of points situated apart from each other, the first and third meshes being situated at inner and outer cortical boundary layers, respectively, of the cerebral cortex and the second mesh being situated between the first and third meshes; and/or for each of a plurality of points of the second mesh: determining a closest point of the first mesh and a closest point of the third mesh, determining a distance between the corresponding closest point of the first mesh and the corresponding closest point of the third mesh, and/or associating the determined distance with the corresponding point of the plurality of points of the second mesh.

It is also envisioned that the method may further include an act of mapping the associated distance for each of the plurality of points of the second mesh in accordance with a mapping method to form content. Further, the method may include an act of rendering the content on a display. In accordance with embodiments of the method, the mapping method may selected by a user from a plurality of mapping methods rendered on a display and stored in a memory of the system for later use. The method may further include an act of associating the points of the first and third meshes, which are determined to be closest to the same point on the second mesh, with each other. It is also envisioned that the method may further include an act of determining a cortical thickness at one or more selected points of the plurality of points of the second mesh based upon the determined distance associated with the selected point of plurality of points of the second mesh.

In accordance with yet other embodiments of the present system, there is disclosed a computer program stored on a computer readable memory medium, the computer program may be configured to determine measurements, the computer program may include a program portion configured to: obtain magnetic resonance (MR) scan information of a region-of-interest (ROI) of at least a portion of a cerebral cortex of a subject; form first, second and third meshes each comprising a plurality of points situated apart from each other, the first and third meshes being situated at inner and outer cortical boundary layers, respectively, of the cerebral cortex and the second mesh being situated between the first and third meshes; and/or for each of a plurality of points of the second mesh: determine a closest point of the first mesh and a closest point of the third mesh, determine a distance between the corresponding closest point of the first mesh and the corresponding closest point of the third mesh, and/or associate the determined distance with the corresponding point of the plurality of points of the second mesh.

The portion may be further configured to map the associated distance for each of the plurality of points of the second mesh in accordance with a mapping method to form content. It is also envisioned that the program portion may be further configured to render the content on a display. Moreover, the program portion may be further configured to render a menu for a user to select the mapping method from a plurality of mapping methods. It is further envisioned that the program portion may be further configured to associate the points of the first and third meshes, which are determined to be closest to the same point on the second mesh, with each other. It is further envisioned that the program portion may be further configured to determine a cortical thickness at one or more selected points of the plurality of points of the second mesh based upon the determined distance associated with the selected point.

The invention is explained in further detail, and by way of example, with reference to the accompanying drawings wherein:

FIG. 1A shows a T1w scan of an axial-cross section of a cerebral cortex depicted as the outermost dark area;

FIG. 1B shows a T1w scan of a coronal cross-section of the cerebral cortex;

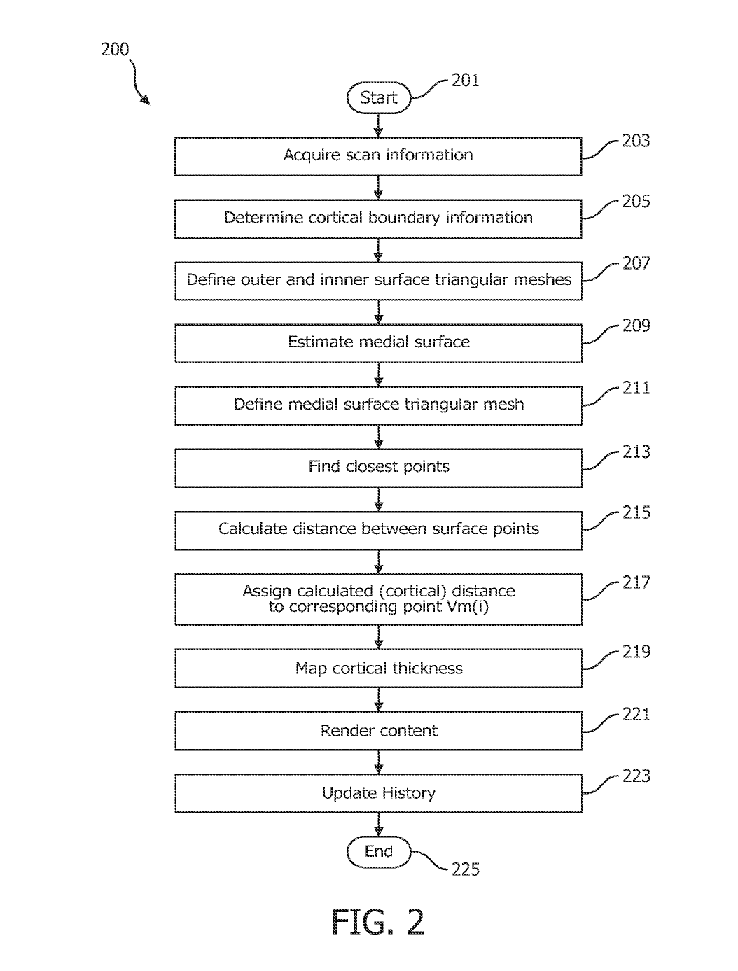

FIG. 2 is a flow diagram that illustrates a process performed by a system in accordance with embodiments of the present system;

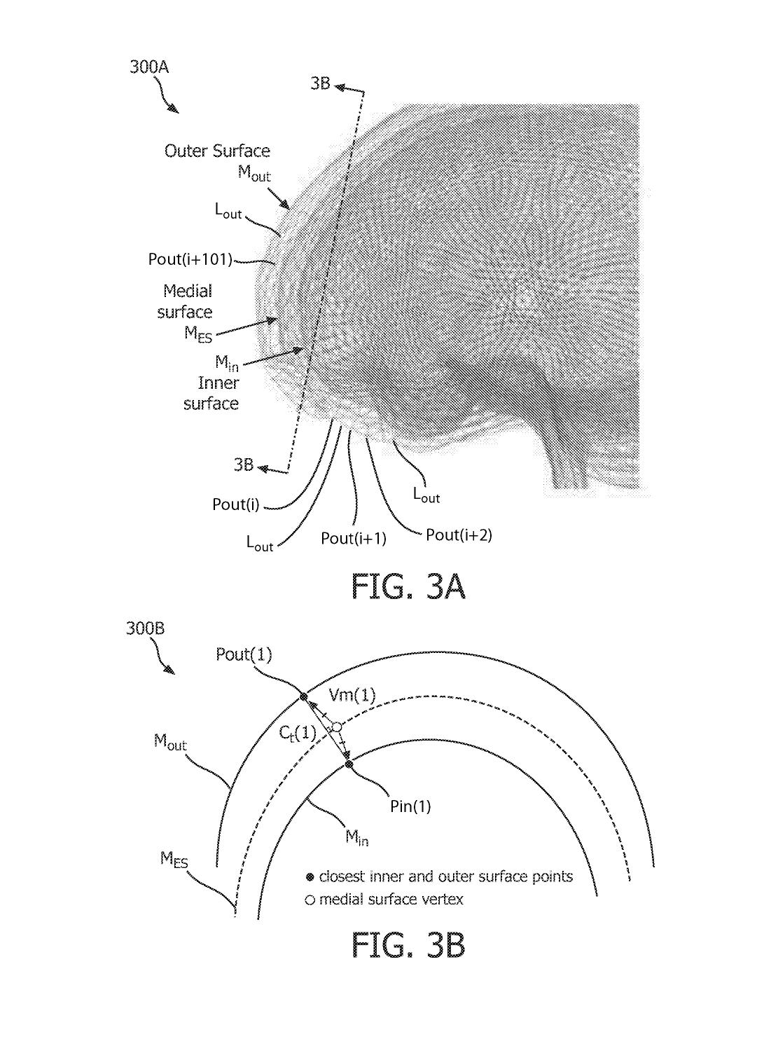

FIG. 3A shows a graph of partial 3-D profile illustrating cortical boundaries in accordance with embodiments of the present system;

FIG. 3B shows a graph of 2-D cut taken along lines 3B-3B of profile illustrating inner and outer boundaries Mᵢₙ and Mₒᵤₜ, respectively, in accordance with embodiments of the present system;

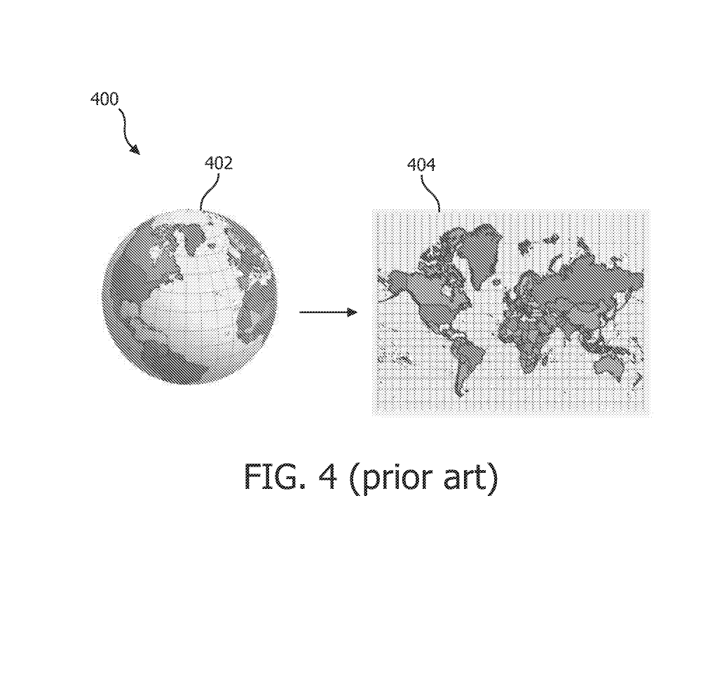

FIG. 4 shows a 2-D representation of a 3-D sphere mapped in accordance with a conventional mapping method;

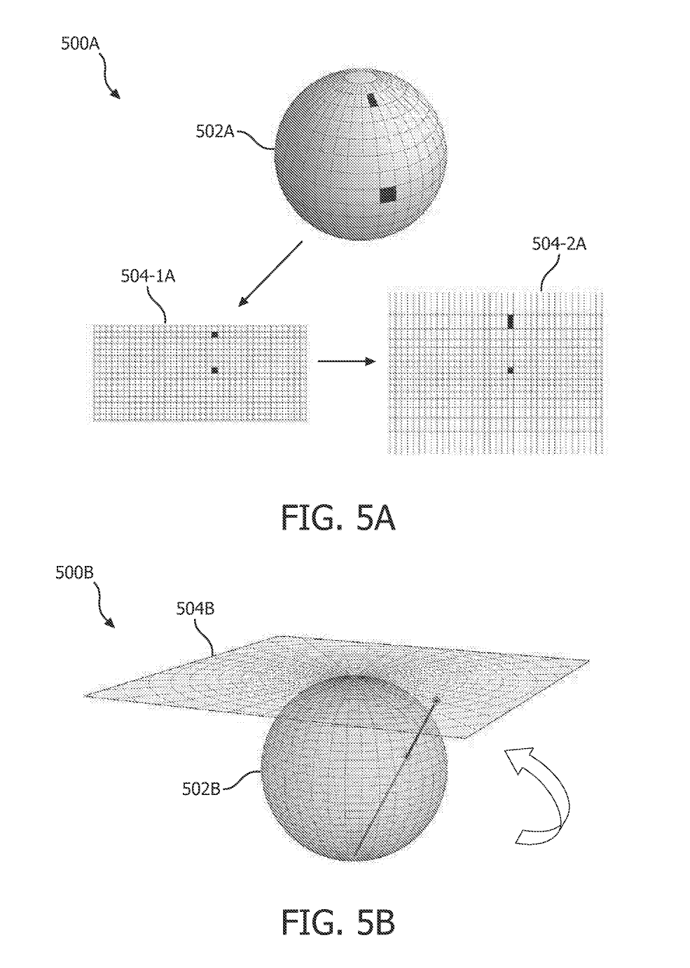

FIG. 5A shows a mapping method using equal and variable planar increments for mapping a 3-D object such as a sphere to planar surfaces in accordance with embodiments of the present system;

FIG. 5B shows a mapping method which uses planar mapping in cylindrical coordinates that maps the sphere to a planar circle in accordance with embodiments of the present system;

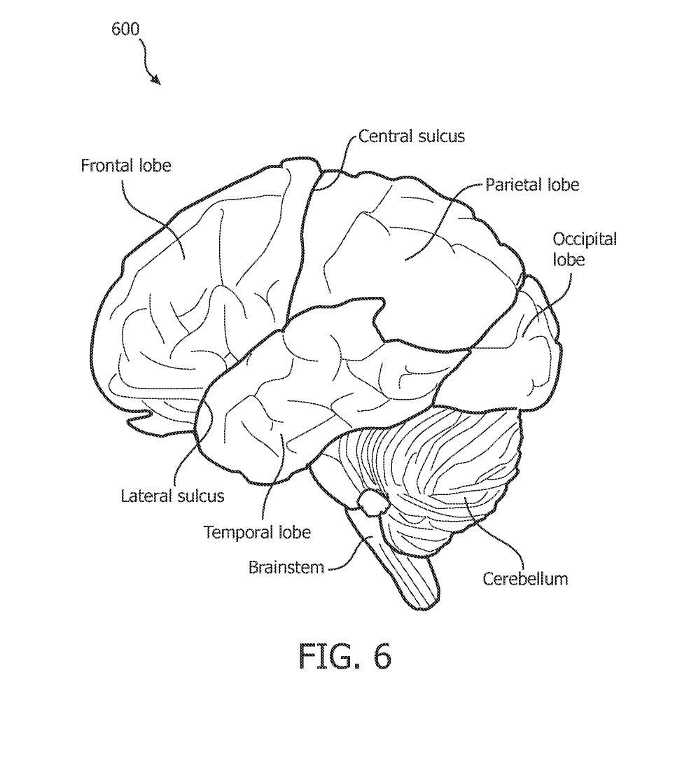

FIG. 6 is a diagram illustrating a side view of the lobes of a human cerebral cortex;

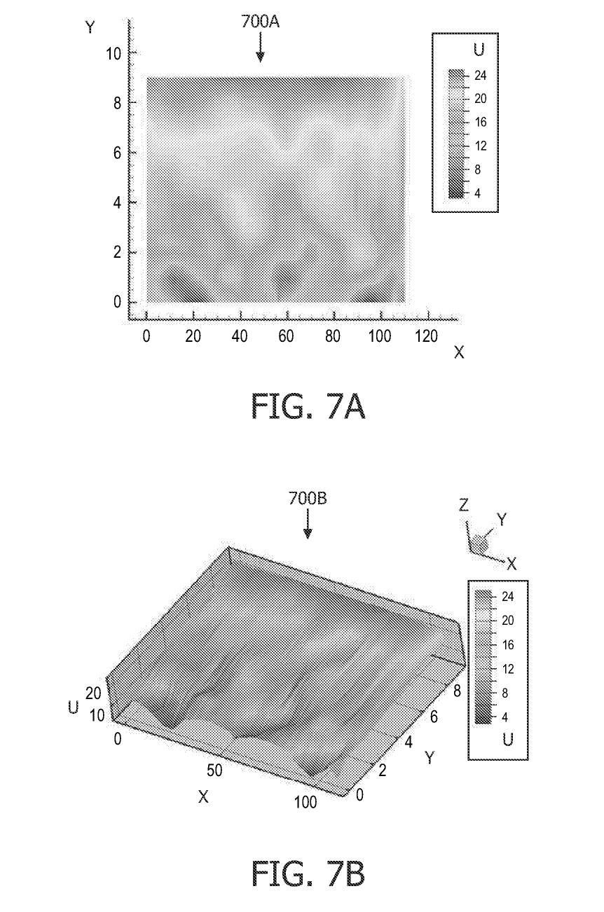

FIG. 7A shows a 2-D plot of cortical thickness obtained in accordance with embodiments of the present system;

FIG. 7B shows a 3-D surface plot of cortical thickness obtained in accordance with embodiments of the present system; and

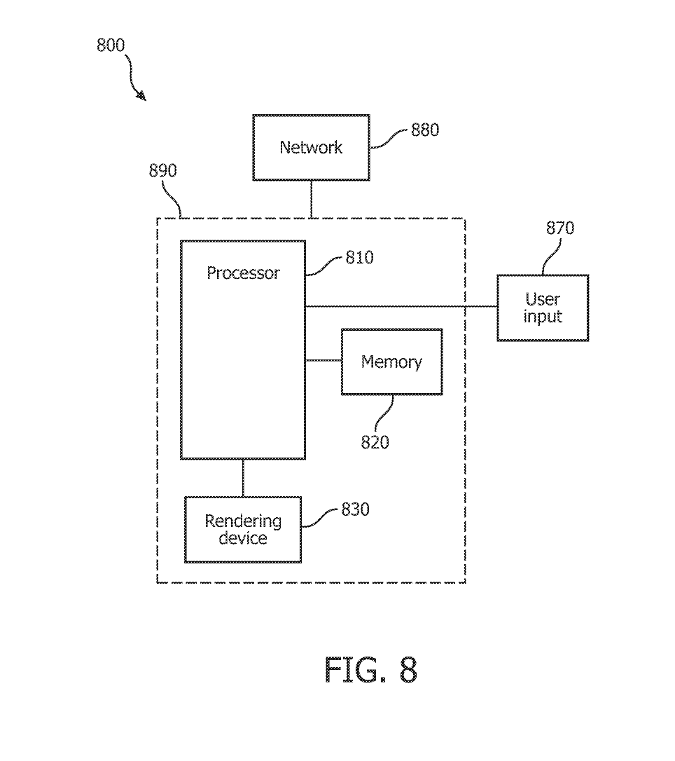

FIG. 8 shows a portion of a system in accordance with an embodiment of the present system.

The following are descriptions of illustrative embodiments that when taken in conjunction with the following drawings will demonstrate the above noted features and advantages, as well as further ones. In the following description, for purposes of explanation rather than limitation, illustrative details are set forth such as architecture, interfaces, techniques, element attributes, etc. However, it will be apparent to those of ordinary skill in the art that other embodiments that depart from these details would still be understood to be within the scope of the appended claims. Moreover, for the purpose of clarity, detailed descriptions of well known devices, circuits, tools, techniques, and methods are omitted so as not to obscure the description of the present system. It should be expressly understood that the drawings are included for illustrative purposes and do not represent the scope of the present system. In the accompanying drawings, like reference numbers in different drawings may designate similar elements.

The term rendering and formatives thereof as utilized herein refer to providing information, such as for visualization of plots etc., such that it may be perceived by at least one user sense, such as a sense of sight. For example, the present system may render a user interface on a display device so that it may be seen, interacted with and/or otherwise perceived by a user. The term rendering may also comprise all the actions required to generate the display of information, whether it be graphical, textual, etc., on a display device.

FIG. 2 is an exemplary flow diagram that illustrates a process 200 performed by a system such as a measurement system in accordance with embodiments of the present system. The process 200 may be performed using one or more processors, computers, etc., communicating over a network and may obtain information from, and/or store information to one or more memories which may be local and/or remote from each other. The process 200 may include one of more of the following acts. Further, one or more of these acts may be combined and/or separated into sub-acts, if desired. Further, one or more of these acts may be skipped depending upon settings. In operation, the process may start during act 201 and then proceed to act 203.

During act 203, the process may acquire imaging information of a region-of-interest (ROI) using any suitable imaging method or methods. For example, in accordance with embodiments of the present system, MR scan information may be acquired of a ROI using a suitable MR method such as a T1-weighted (T1w) structural MR scan. The scan information may include information related to a cortex of a subject-of-interest (SOI) such as a patient and may include information related to an intensity variation on cortical boundaries of the cortex. The MR scan information may be acquired in real time (e.g., from a current scan) or may be acquired from a memory of the system, such as one saved from a prior scan. For the sake of simplicity, it is assumed that the present system is previously trained to recognize cortical boundaries such as may be determined in accordance with a shape-constrained deformable model based upon a set of parcellated training data (PTD) such as may be obtained from a memory of the system. Further, it is envisioned that in some embodiments, the ability to identify information related to the intensity variation on the cortical boundaries may be determined using a set of PTD and may be incorporated into a segmentation process performed in accordance with embodiments of the present system. After completing act 203, the process may continue to act 205.

During act 205, the process may determine cortical boundary information (CBI) related to cortical boundaries of the cortex of the subject from the MR scan information. The CBI may include information related to location and intensity variation of the cortical boundaries of the MR scan information such as the inner and outer boundaries of the cortex. Any suitable method to determine the inner and outer cortical boundaries of the CBI may be used. The CBI may include 2- or 3-Dimensional information related to (locations, etc.) of the inner and outer boundaries of the cortex. However, in the present embodiment, for the sake of simplicity, it will be assumed that the CBI includes three-dimensional (3D) information. However, as readily appreciated, the present system may utilize 2-Dimensional information in accordance with embodiments of the present system. For example, the present system may identify the boundaries of the cortex as a cortical mesh (e.g., a set of connected points defining the boundaries of the cortex, such as defined by a series of connected polygons). After completing act 205, the process may continue to act 207.

During act 207, the process may define outer and inner meshes, Mᵢₙ and Mₒᵤₜ, respectively, to be applied to the outer and inner cortical boundaries, respectively, in accordance with the determined CBI. Thus, the process may represent inner and outer cortical boundaries using the inner and outer meshes. For example, FIG. 3A shows a graph 300A of partial 3-D profile illustrating cortical boundaries in accordance with embodiments of the present system. The inner and outer meshes are shown as Miᵢₙ and Mₒᵤₜ, respectively. FIG. 3B shows a graph 300B of 2-D cut taken along lines 3B-3B of profile 300A illustrating inner and outer boundaries Miₙ and Mₒᵤₜ, respectively, in accordance with embodiments of the present system. Each of the inner and outer meshes Mᵢₙ and Mₒᵤₜ, respectively, (generally Mx) may include a series of points (e.g., vertices) which are interconnected to form a polygonal shape such as triangles in the present embodiments. Thus, the inner and outer meshes Mx may each be considered a triangular mesh. Thus, triangles connect points (e.g., vertices) of the same mesh to form mesh faces and the inner and outer meshes Mx may each include their own set of triangles.

Referring to FIGS. 3A and 3B, the outer and inner triangular meshes Mᵢₙ and Mₒᵤₜ, respectively, may each include a plurality of vertices known as points pₒᵤₜ(i) and pᵢₙ(i) for each of a plurality of points (i, i+1, . . . l, where l may be an integer). Thus, the inner and outer cortical boundaries may be represented as inner and outer meshes Mᵢₙ and Mₒᵤₜ, respectively, formed from polygons such as triangles (in the present embodiments) in which vertices (e.g., points pₒᵤₜ(i) and pᵢₙ(i), respectively) of the triangles are shared with adjacent triangles of the same mesh. Although triangular meshes are shown, the meshes may include other polygonal shapes, if desired. A one-to-one mapping (correspondence) between meshes (e.g., triangles in the illustrative embodiment shown) of the inner and outer meshes Mᵢₙ and Mₒᵤₜ, respectively, may be established. Further, points pₒᵤₜ(i) may be connected adjacent points pₒᵤₜ(i) by outer links Lₒᵤₜ and points pᵢₙ(i) may be connected to adjacent points pᵢₙ(i) by inner links Lᵢₙ. After completing act 207, the process may continue to act 209.

During act 209, the process may estimate a medial surface (M_{ES}) of the cortical mantle based upon the inner and outer surfaces. By definition, the M_{ES} may be at substantially the same distance from both boundary surfaces of the inner and outer meshes. After completing act 209, the process may continue to act 211.

During act 211, the process may define a medial triangular mesh M_{ed} to be applied to the estimated medial surface (M_{ES}) of the cortical mantle. The medial triangular mesh M_{ed} may include a plurality of vertices known as points vₘ(i), (i, i+1, . . . l, where l may be an integer). The points vₘ(i) of the medial triangular mesh M_{ed} may be connected to adjacent points vₘ(i) so as to form a polygonal shape (e.g., a triangular shape) similarly to the polygonal shape (e.g. triangular in the present embodiments) of inner and outer triangular meshes Mᵢₙ and Mₒᵤₜ, respectively. The medial triangular mesh M_{ed} may have the same number of points and/or triangles as the inner and outer meshes Mx. After completing act 211, the process may continue to act 213.

During act 213, the process may find, for each point vₘ(i) of the plurality of points vₘ(i) on the medial (triangular) mesh M_{ed}, closest outer and inner surface points pₒᵤₜ(i) and pᵢₙ(i), respectively and may associate these closest points as a point set. Although a one-to-one correspondence may be established between each of the inner and outer meshes Mᵢₙ and Mₒᵤₜ, respectively, and the medial mesh M_{ed}, the closest points may or may not have the same index values (e.g., value of index i).

For example, for an arbitrary point of the medial mesh M_{ed} such as vₘ(1) the process may determine that the closest outer and inner surface points pₒᵤₜ(i) and pᵢₙ(i) may be pₒᵤₜ(1) and pᵢₙ(2), respectively. Thus, the point set for vₘ(1) would include pₒᵤₜ(1) and pᵢₙ(2). For example, for another arbitrary point of the medial mesh M_{ed} such as vₘ(10) (e.g., the tenth point set) the process may determine that the closest outer and inner surface points pₒᵤₜ(i) and pᵢₙ(i) may be pₒᵤₜ(9) and pᵢₙ(13), respectively. And, for yet another arbitrary point of the medial mesh M_{ed} such as vₘ(20) (e.g., the twentieth point set) the process may determine that the closest outer and inner surface points pₒᵤₜ(i) and pᵢₙ(i) may be pₒᵤₜ(20) and pᵢₙ(20), respectively. Thus, for any point on the medial mesh and the associated inner and outer surface points of the corresponding point set, the indexes may, or may not, match to each other.

The process may use any suitable algorithm(s), application(s), and/or method(s) to find the closest outer and inner surface points pₒᵤₜ(i) and pᵢₙ(i), respectively, for any point vₘ(i) on the medial mesh M_{ed}. For example, in some embodiments, the process may start with an arbitrary point vₘ(1) of the medial mesh and then determine closest points pₒᵤₜ(x) and pᵢₙ(x)) of the inner and outer meshes Mᵢₙ and Mₒᵤₜ, respectively. One or more of these points may have the same or different indexes (e.g., values of i). The process may perform this act for each point of the medial mesh M_{ed}. After completing act 213, the process may continue to act 215.

During act 215, for each point vₘ(i) of the plurality of points vₘ(i) on the medial triangular mesh M_{ed}, the process may calculate (e.g. using Euclidian methods) a distance between the associated outer and inner surface points pₒᵤₜ(i) and pᵢₙ(i) which form the associated point set. This distance may be set to, and referred to, as a cortical thickness Cₜ(i) for the i^{th} point set. This may enforce symmetry of measurement. The process may perform this act using any suitable algorithms, applications, and/or methods.

For example, using the example, discussed above, for the first point set where the points of this set were defined as vₘ(1), pᵢₙ(1), and pₒᵤₜ(2), the process may determine the distance between pₒᵤₜ(1) and pᵢₙ(2). Thereafter the process may set this distance as a corresponding cortical thickness Cₜ(1) for the first point set (e.g,. the point set of vₘ(1). After completing act 215, the process may continue to act 217.

During act 217, the process may assign the calculated cortical thickness Cₜ(i) (e.g., calculated during act 215) for each corresponding point set to the corresponding (vertex) point vₘ(i). Thus, the process may assign the i^{th} calculated cortical thickness Cₜ(i) to its corresponding i^{th} point vₘ(i). After completing act 217, the process may continue to act 219.

During act 219, the process may perform a mapping process to represent and/or transform the measured cortical thickness Cₜ(i) for each corresponding point vₘ(i) (or selected points vₘ(i)) of the plurality of points (vₘ(l), as may be selected by the system and/or user) on the medial triangular mesh M_{ed} to a 2-D plot, a 3-D surface plot (e.g., a height plot, etc.), etc. Accordingly, the process may form corresponding content which may include, information for rendering a 2-D and/or 3-D plot or plots including a representation of the determined cortical thickness Cₜ(i) for each corresponding point vₘ(i) of the plurality of points vₘ(i)) of the medial triangular mesh. It is further envisioned that the process may render the cortical thickness Cₜ(i) for selected corresponding points vₘ(i) which may be selected by the user and/or system or at points vₘ(i) of the medial triangular mesh within a certain area or volume, if desired. For example, in accordance with embodiments of the present system, the process may represent/transform the measured cortical thickness Cₜ(i) for each corresponding point vₘ(i) in the parametric space of the medial surface for visualization of the cortical thickness using a desired plot type such as a 2-D plot or 3-D surface (height plot) as may be desired by, for example, the system, a user, etc.

For example, in accordance with embodiments of the present system, the process may transform (e.g., map) each of the i^{th} (vertex) points vₘ(i) of the medial triangular mesh M_{ed} and its associated (assigned) cortical thickness Cₜ(i) into a 2-D or 3-D plot form suitable for rendering. For example, FIG. 7A shows a 2-D (x-y) plot 700A of cortical thickness obtained in accordance with embodiments of the present system. FIG. 7B shows a 3-D surface plot 700B of cortical thickness obtained in accordance with embodiments of the present system. In FIGS. 7A and 7B one or more landmarks may be marked such as shown by landmark (xx).

For example, if plotted against a parametric shape of the medial (triangular) mesh M_{ed} surface, the measured cortical thickness Cₜ(i) at points vₘ(i) may be visualized as a 2-D plot such as shown in the plot 700A or as a 3-D surface such as is shown in the plot 700B, as illustrated in FIG. 7B. Accordingly, the process may form a representation which provides a unique quantitative encoding of the cortical thickness. Further, embodiments of the present system may obtain information related to 3-D surfaces and associated cortical thickness determinations from different patients and compare this information in the same parametric space instead of comparing average scalar thickness values and introducing unwanted dimensional reduction. As shown in plots 700A and 700B, the axes may represent a parametric space and may have arbitrary values.

Further, in accordance with embodiments of the present system, the cortical surface thickness Cₜ(i) at points vₘ(i) may be parameterized in spherical coordinates and mapped to a planar rectangle. This type of mapping may follow, for example, cartographic rules, and may be similar to known mapping methods such as a commonly known Mercator mapping method. An illustration of the method is provided in FIG. 4 which shows a 2-D representation of a 3-D sphere mapped in accordance with a conventional mapping method. FIG. 5A shows a mapping method using equal and variable planar increments for mapping a 3-D object such as a sphere 502A to planar surfaces 504-1 A and 504-2A in accordance with embodiments of the present system. FIG. 5B shows a mapping method which uses planar mapping in cylindrical coordinates that maps the sphere 502B to a planar circle 504B in accordance with embodiments of the present system. It is also envisioned that in some embodiments, a plot style (e.g., 2-D, 3-D, as well as graph type, e.g., pie chart, line graph, etc.) may be selected by the system and/or user, if desired.

In accordance with yet other embodiments, the process may map selected areas such as landmarks (e.g., regions, areas, and/or points) of the sphere to the planar area. FIG. 6 is a diagram 600 illustrating a side view of the lobes of a human cerebral cortex. The cerebral cortex of a human is highly convoluted and includes elevated convolutions on the cortical surface called gyri which are separated by grooves called sulci or, if they are particularly deep, these grooves may be known as fissures. The cerebral cortex has two hemispheres which are separated by a sagittal fissure. While the guri and sulci are topologically different from one person to another, the four lobes of the cerebral cortex: frontal, parietal, occipital and temporal, are very well defined and common for all people. Therefore, a set of common points (e.g., points of interest (POI)) which represent lobe landmarks (e.g., see, landmark (xx)) may be reliably extracted. In accordance with embodiments of the present system, cortical thickness may be measured at these landmarks, in spherical coordinates, and the measured values may be mapped to a planar rectangle for surface/height fitting. It is also envisioned that the landmarks may be viewed as a sparse set of points. After completing act 219, the process may continue to act 221.

During act 221, the process may render the content (e.g., formed during act 219 and which may include the 2-D or 3-D plots) using any suitable rendering device such as a display (e.g., 2-D or 3-D), a projector, a speaker, etc. The process may further generate and/or form one or more menus so that a user may interact with the process and make certain selections and/or input desired commands, such as rotate, shift right/left/up/down, increase/decrease size, select/change graphs and/or images, highlight, select, etc. Accordingly, for example, a user may select, magnify, rotate, etc., one or more portions of the rendered content. After completing act 221, the process may continue to act 223.

During act 223, the process may update history information by, for example, storing information obtained by and/or generated by the process in a memory of the system for later use. For example, the process may store the information related to the cortical thickness and associated vertex points Vₘ(i), generated content, etc. After completing act 223, the process may continue to act 225, where it ends.

In accordance with embodiments of the present system, the correspondence between mesh triangles on the inner and outer meshes enforces symmetry in the cortical thickness measurements and results in increased accuracy over current methods to determine cortical thickness which may be considered to be non-symmetric. In non-symmetric methods the cortical thickness may vary based upon a direction in which the cortical thickness is determined (e.g., from the inner to the outer meshes or from the outer to the inner meshes). This problem is due to the fact that for an inner surface point (Pᵢₙ), a nearest point on an outer surface may be (Pₒᵤₜ). However, the inner surface point (Pᵢₙ) may not correspond to the nearest point for the outer surface point (Pₒᵤₜ). This variation may decrease accuracy.

In accordance with embodiments of the present system, corresponding inner and outer surface vertices will have the same closest medial surface point. Using the medial surface to establish correspondence between inner and outer points may result in the same cortical thickness measurement regardless of the traversing direction (inward-to-outward or outward-to-inward) and thereby, improves the accuracy and repeatability of these measurements.

In accordance with embodiments of the present system, deformable segmentation methods may be used to adapt a mesh to each of inner and outer boundaries of a cortex, or alternatively, to seed a voxel based approach for segmentation of both. Prior information about an intensity variation on the cortical boundaries may be obtained from a set of parcellated training data and may be incorporated into a segmentation method in accordance with embodiments of the present system. For the sake of clarity, it will be assumed that both of the inner and outer boundaries of the cortex may be identified and corresponding information may be available.

Generally, the inner and outer cortical boundaries may be represented as triangular meshes (e.g., Mᵢₙ and Mₒᵤₜ, respectively) as discussed. A one-to-one mapping (correspondence) between mesh triangles may be established and the medial surface of a mesh representing the cortical mantle may be estimated. The cortical thickness may be measured as a scalar distance from a medial surface vertex (e.g., vₘ(i)) to corresponding closest points on the inner or outer surfaces pᵢₙ(i) and pₒᵤₜ(i), respectively. The medial surface is assumed by definition to be located at the same distance from both boundary surfaces (e.g., inner or outer surfaces pᵢₙ(i) and pₒᵤₜ(i).

The correspondence between mesh triangles on the inner and outer surfaces enforces symmetry in the measurements. Corresponding inner and outer surface vertices (e.g., pᵢₙ(i) and pₒᵤₜ(i), respectively) may have the same closest medial surface point (e.g., vₘ(i) as described herein). This may result in the same cortical thickness measurement regardless of the traversing direction (e.g., inward-to-outward or outward-to-inward). This may enforce symmetry in measurements obtained in accordance with embodiments of the present system.

In yet other embodiments, the process may store the determined cortical thickness for the plurality of points of the second mesh in a memory of the system. Then, at a later time during a subsequent test, the process may determine current values for the determined cortical thickness for a plurality of points of the second mesh and compare these values with the previously-stored cortical thickness values to determine a result (e.g., using a subtraction method). If the result of the comparison is determined to be less than a threshold value associated with a corresponding point of the plurality of points of the second mesh, the process may highlight an area mapped to the corresponding point of the second mesh. However, if a result of the comparison is determined to be greater than or equal to the threshold value associated with a corresponding point of the plurality of points of the second mesh, the process may ignore the area mapped to the corresponding point of the second mesh. Then, the process may render on a user interface of the system a representation of the cortical thickness at one or more of the plurality of points of the second mesh for which the cortical thickness was determined and may overlay the highlighting of the area mapped to the corresponding point of the second mesh. The process may also store information related to the cortical thickness and determine a rate of change for the cortical thickness at one or more of the plurality of points of the second mesh for which the cortical thickness was determined. Then the process may render results on a display of the system for the convenience of the user. Thus, the process may render a representation of cortical thickness and changes of cortical thickness on a display of the system for the convenience of the user.

FIG. 8 shows a portion of a system 800 in accordance with an embodiment of the present system. For example, a portion of the present system 800 may include a processor 810 (e.g., a controller) operationally coupled to a memory 820, a rendering device 830 (a display such as may provide a user interface, plots, etc.), and a user input device 870. The memory 820 may be any type of device for storing application data as well as other data related to the described operation. The application data and other data are received by the processor 810 for configuring (e.g., programming) the processor 810 to perform operation acts in accordance with the present system. The processor 810 so configured becomes a special purpose machine particularly suited for performing in accordance with embodiments of the present system.

The operation acts may include configuring the system 800 by, for example, configuring the processor 810 to obtain information from user inputs, a network 880 (e.g., such as from an MR imaging device), and/or the memory 820 and processing this information in accordance with embodiments of the present system to obtain information related to cortical thickness of a patient in accordance with embodiments of the present system. The user input portion 870 may include a keyboard, a mouse, a trackball and/or other device, including touch-sensitive displays, which may be stand alone or be a part of a system, such as part of an MR imaging device, a personal computer, a notebook computer, a netbook, a tablet, a smart phone, a personal digital assistant (PDA), a mobile phone, and/or other device for communicating with the processor 810 via any operable link. The user input portion 870 may be operable for interacting with the processor 810 including enabling interaction within a UI as described herein. Clearly the processor 810, the memory 820, the UI 830 and/or user input device 870 may all or partly be a portion of a computer system or other device as described herein.

Operation acts may include requesting, providing, forming and/or rendering of information such as, for example, information related to determined cortical thicknesses, etc. The processor 810 may render the information such as on a display (e.g., the rendering device 830) of the system.

The methods of the present system are particularly suited to be carried out by processor programmed by a computer software program, such program containing modules corresponding to one or more of the individual steps or acts described and/or envisioned by the present system.

The processor 810 is operable for providing control signals and/or performing operations in response to input signals from the user input device 870 as well as in response to other devices of the network 880 and executing instructions stored in the memory 820. The processor 810 may include one or more of a microprocessor, an application-specific or general-use integrated circuit(s), a logic device, etc. Further, the processor 810 may be a dedicated processor for performing in accordance with the present system or may be a general-purpose processor wherein only one of many functions operates for performing in accordance with the present system. The processor 810 may operate utilizing a program portion, multiple program segments, or may be a hardware device utilizing a dedicated or multi-purpose integrated circuit.

Further variations of the present system would readily occur to a person of ordinary skill in the art and are encompassed by the following claims. The present system provides a novel method of determining and visualizing cortical thickness. This system may be used as a result for cortical studies and/or may be provide a novel cortical thickness descriptor as an imaging “biomarker” of neurodegenerative pathology.

Finally, the above-discussion is intended to be merely illustrative of the present system and should not be construed as limiting the appended claims to any particular embodiment or group of embodiments. Thus, while the present system has been described with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

The section headings included herein are intended to facilitate a review but are not intended to limit the scope of the present system. Accordingly, the specification and drawings are to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof;

f) hardware portions may be comprised of one or both of analog and digital portions;

g) any of the disclosed devices or portions thereof may be combined together or separated into further portions unless specifically stated otherwise;

h) no specific sequence of acts or steps is intended to be required unless specifically indicated; and

i) the term “plurality of” an element includes two or more of the claimed element, and does not imply any particular range of number of elements; that is, a plurality of elements may be as few as two elements, and may include an immeasurable number of elements.

1. A measurement apparatus, comprising:
at least one controller which is configured to:
obtain magnetic resonance (MR) scan information of a region-of-interest of at least a portion of a cerebral cortex of a subject;
form first, second, and third meshes each comprising a plurality of points situated apart from each other, the first and third meshes being situated at inner and outer cortical boundary layers, respectively, of the cerebral cortex and the second mesh being between corresponding points of the first and third meshes; and
for each of a plurality of points of the second mesh:
determine a closest point of the first mesh and a closest point of the third mesh,
determine a distance between the corresponding closest point of the first mesh and the corresponding closest point of the third mesh, and
associate the determined distance with the corresponding point of the plurality of points of the second mesh.

2. The apparatus of claim 1, wherein the obtained MR scan information is three-dimensional (3D) magnetic resonance (MR) scan information and the at least one controller is further configured to map the associated distance for each of the plurality of points of the second mesh in accordance with a mapping method to form content.

3. The apparatus of claim 2, wherein the at least one controller is further configured to render the content on a display.

4. (canceled)

5. The apparatus of claim 1, wherein the at least one controller is further configured to associate the points of the first and third meshes, which are determined to be closest to the same point on the second mesh, with each other.

6. The apparatus of claim 1, wherein the at least one controller is further configured to determine a cortical thickness at one or more selected points of the plurality of points of the second mesh based upon the determined distance associated with the selected point.

7. A method of measuring, the method performed by at least one controller of an imaging system and comprising acts of:
obtaining magnetic resonance (MR) scan information of a region-of-interest of at least a portion of a cerebral cortex of a subject;
forming first, second and third meshes each comprising a plurality of points situated apart from each other, the first and third meshes being situated at inner and outer cortical boundary layers, respectively, of the cerebral cortex and the second mesh being calculated to be between corresponding points of the first and third meshes; and
for each of a plurality of points of the second mesh:
determining a closest point of the first mesh and a closest point of the third mesh,
determining a distance between the corresponding closest point of the first mesh and the corresponding closest point of the third mesh, and
associating the determined distance with the corresponding point of the plurality of points of the second mesh.

8. The method of claim 7, wherein the obtained magnetic resonance (MR) scan information is three-dimensional (3D) magnetic resonance (MR) scan information, the method further comprising an act of mapping the associated distance for each of the plurality of points of the second mesh in accordance with a mapping method to form content.

9. The method of claim 8, further comprising an act of rendering the content on a display.

10. The method of claim 8, wherein the mapping method is selected by a user from a plurality of mapping methods rendered on a display.

11. (canceled)

12. The method of claim 7, further comprising an act of determining a cortical thickness at one or more selected points of the plurality of points of the second mesh based upon the determined distance associated with the selected point.

13. A computer readable non-transitory memory medium including a computer program stored thereon, the computer program comprising:
a program portion, when executed by a controller, configured to:
obtain magnetic resonance (MR) scan information of a region-of-interest (ROI) of at least a portion of a cerebral cortex of a subject;
form first, second and third meshes each comprising a plurality of points situated apart from each other, the first and third meshes being situated at inner and outer cortical boundary layers, respectively, of the cerebral cortex and the second mesh being calculated to be between corresponding points of the first and third meshes; and
for each of a plurality of points of the second mesh:
determine a closest point of the first mesh and a closest point of the third mesh,
determine a distance between the corresponding closest point of the first mesh and the corresponding closest point of the third mesh, and
associate the determined distance with the corresponding point of the plurality of points of the second mesh.

14. The memory medium of claim 13, wherein the obtained MR scan information is three-dimensional (3D) magnetic resonance (MR) scan information and the program portion is further configured to map the associated distance for each of the plurality of points of the second mesh in accordance with a mapping method to form content.

15. The memory medium of claim 14, wherein the program portion is further configured to render the content on a display.

16. (canceled)

17. The memory medium of claim 13, wherein the program portion is further configured to associate the points of the first and third meshes, which are determined to be closest to the same point on the second mesh, with each other.

18. The memory medium of claim 13, wherein the program portion is further configured to determine a cortical thickness at one or more selected points of the plurality of points of the second mesh based upon the determined distance associated with the selected point.
